(19) United States
(12) Patent Application Publication
(10) Pub. No.: US 2014/0306582 A1
(43) Pub. Date: Oct. 16, 2014

(54) ELECTRONIC COMPONENT, ELECTRONIC APPARATUS, AND MOVING OBJECT

(71) Applicant: SEIKO EPSON CORPORATION, Tokyo (JP)

(72) Inventors: Juichiro MATSUZAWA, Minowa (JP); Masaru MIKAMI, Minowa (JP); Toshiya USUDA, Ina (JP)

(73) Assignee: SEIKO EPSON CORPORATION, Tokyo (JP)

(21) Appl. No.: 14/248,641

(22) Filed: Apr. 9, 2014

(30) Foreign Application Priority Data
Apr. 12, 2013 (JP) 2013-083821

(51) Int. Cl. H01L 41/047

(52) U.S. Cl. CPC H01L 41/0475
USPC 310/366

(57) ABSTRACT

An oscillator as an electronic component includes external connection terminals as terminals disposed on a reverse side of a substrate constituting a package, and connection electrodes connected respectively to the external connection terminals, and penetrating through the substrate, and the center of the connection electrode as a second connection electrode in the three connection electrodes adjacent to each other is disposed at a position out of an imaginary line passing through the center of the connection electrode as a first connection electrode and the center of the connection electrode as a third connection electrode.

### BACKGROUND

1. Technical Field

The present invention relates to an electronic component, and an electronic apparatus and a moving object using the electronic component.

2. Related Art

In the past, there has been known a resonation device using a ceramic package as an example of the electronic component. In this resonation device, since the number of external connection terminals (the number of pins) for mounting the resonation device on a mounting board is not so large, it has been possible to realize the electrical connection between internal wiring and the external connection terminals using lateral electrodes (castellations) disposed on the lateral surface of the package. However, in recent years, resonation devices have been required to be miniaturized and multi-functioned, and thus, the resonation device housed in a package (hereinafter referred to as a “small-sized multi-pin package”) small in size and large in the number of external terminals (the number of pins) has been required.

In the resonation device with such a small-sized multi-pin package, the case in which it is difficult to realize the connection between the internal wiring and the external connection terminals only with the lateral electrodes (the castellations) has become to occur on the grounds that, for example, the pattern of the internal wiring is complicated. In order to cope with this problem, a connection method using through electrodes (via holes) has been adopted (see, e.g., JP-A-2008-109181, JP-A-2011-155444, and JP-A-2013-31133).

However, if such through electrodes as described above are arranged in a straight line (like perforations) on the bottom of the package, it results that the parts small in length located between the through electrodes are arranged in a straight line (like perforations), and the package strength in the portion where the through electrodes are arranged side by side in a straight line might be decreased. In the case in which such a resonation device has been installed in the mounting board, a flexural stress or the like generated in the mounting board is applied to the portion where the through electrodes are arranged in a straight line and thus the strength is lower than in other portions, and there has been a possibility of causing a crack in the portion with the through electrodes arranged in a straight line.

### SUMMARY

An advantage of some aspects of the invention is to solve at least a part of the problems described above, and the invention can be implemented as the following forms or application examples.

### Application Example 1

This application example is directed to an electronic component including a substrate, a second connection electrode provided with a second hole extending from one surface of the substrate toward another surface, which is a reverse side with respect to the one surface, and a conductor disposed inside the second hole, a first connection electrode adjacent to the second connection electrode, and provided with a first hole extending from the one surface toward the another surface, and a conductor disposed inside the first hole, and a third connection electrode adjacent to the second connection electrode, and provided with a third hole extending from the one surface toward the another surface, and a conductor disposed inside the third hole, a center of the second connection electrode is disposed at a position out of an imaginary line passing through a center of the first connection electrode and a center of the third connection electrode in a plan view of the one surface, a second terminal electrically connected to the second connection electrode, a first terminal electrically connected to the first connection electrode, and a third terminal electrically connected to the third connection electrode are disposed on the one surface, and the second terminal is disposed between the first terminal and the third terminal.

The electronic component according to this application example is provided with the three connection electrodes connected respectively to the second terminal, the first terminal, and the third terminal disposed on one surface of the substrate, namely the second connection electrode electrically connected to the second terminal, the first connection electrode electrically connected to the first terminal, the third connection electrode electrically connected to the third terminal. Further, the first connection electrode and the third connection electrode are disposed so as to be adjacent to the second connection electrode. Further, since the center of the second connection electrode is disposed at the position out of the imaginary line passing through the centers of the first connection electrode and the third connection electrode, the first through third connection electrodes (the three connection electrodes) fail to be arranged in a straight line. Thus, there is eliminated the case in which the part of the substrate low in strength occurs due to the connection electrodes arranged side by side in a straight line, and it becomes possible to provide an electronic component which inhibits the substrate strength from deteriorating to thereby increase the substrate strength.

### Application Example 2

This application example is directed to the electronic component according to the application example described above, wherein the substrate has a rectangular shape in the plan view of the one surface, and a lateral electrode is disposed along a side surface connecting the one surface and the another surface to each other in a corner portion of the substrate.

The corner portion of the substrate is a part where two outer peripheral sides intersect with each other, and if the connection electrode is disposed around the corner portion, the distances between the two outer peripheral sides and the connection electrode are shortened, which might cause the deterioration of the substrate strength. According to this application example, a lateral electrode is disposed along a side surface connecting the one surface and the another surface to each other in the corner portion of the substrate, but no connection electrode is disposed. Therefore, it results that no connection electrode is disposed in the vicinity of the outer peripheral side of the substrate, and therefore, since the distance from the side of the substrate to the connection electrode is elongated, it become possible to increase the substrate strength.

### Application Example 3

This application example is directed to the electronic component according to the application example described above, wherein the first terminal, the second terminal, and the third terminal have internal contact with an outer peripheral side of the substrate.

According to this application example, since the first terminal, the second terminal, and the third terminal have internal contact with the outer peripheral side of the substrate, the surface areas of the first terminal, the second terminal, and the third terminal can be enlarged, and thus, the bonding strength with the mounting board can be increased. Further, since the bonding area with the mounting board is enlarged, the strength of the substrate can also be increased.

### Application Example 4

This application example is directed to the electronic component according to the application example described above, wherein the first connection electrode is disposed inside the first terminal, the second connection electrode is disposed inside the second terminal, and the third connection electrode is disposed inside the third terminal in the plan view of the one surface.

According to this application example, since the part provided with the first through third connection electrodes, and therefore low in the substrate strength is included in the bonding material in the mounting process, the bonding material acts a strength-reinforcing material, and in other words, the bonding material increases the substrate strength. Thus, the breakage of the substrate due to the stress applied after mounting can be prevented.

### Application Example 5

This application example is directed to the electronic component according to the application example described above, wherein the electronic component further includes a circuit element.

According to this application example, it becomes possible to provide an electronic component, which is provided with the circuit element, and inhibits the substrate strength from deteriorating to thereby increase the substrate strength.

### Application Example 6

This application example is directed to an electronic apparatus including the electronic component according to the application example described above.

According to this application example, since the electronic component with the increased substrate strength is used, it is difficult for the damage of the substrate and so on to occur, and thus, it becomes possible to provide an electronic apparatus superior in durability.

### Application Example 7

This application example is directed to a moving object including the electronic component according to the application example described above.

According to this application example, since the electronic component with the increased substrate strength is used, it is difficult for the damage of the substrate and so on to occur, and thus, it becomes possible to provide a moving object superior in durability.

### BRIEF DESCRIPTION OF THE DRAWINGS

The invention will now be described with reference to the accompanying drawings, wherein like numbers reference like elements.

FIGS. 1A and 1B are diagrams schematically showing an electronic component according to a first embodiment of the invention, wherein FIG. 1A is a front cross-sectional view, and FIG. 1B is a bottom view.

FIGS. 2A and 2B are diagrams schematically showing an electronic component according to a second embodiment of the invention, wherein FIG. 2A is a front cross-sectional view, and FIG. 2B is a bottom view.

FIGS. 3A and 3B are bottom views each showing a modified example of an arrangement of connection electrodes.

FIG. 4 is a cross-sectional view showing a cross-section of a modified example of an external terminal at the same position as the cross-section along the A-A line in FIG. 1B.

FIG. 5 is a perspective view showing a configuration of a mobile personal computer as an example of the electronic apparatus.

FIG. 6 is a perspective view showing a configuration of a cellular phone as an example of the electronic apparatus.

FIG. 7 is a perspective view showing a configuration of a digital still camera as an example of the electronic apparatus.

FIG. 8 is a perspective view showing a configuration of a vehicle as an example of a moving object.

### DESCRIPTION OF EXEMPLARY EMBODIMENTS

Some exemplary embodiments of the invention will hereinafter be described with reference to the accompanying drawings.

### First Embodiment

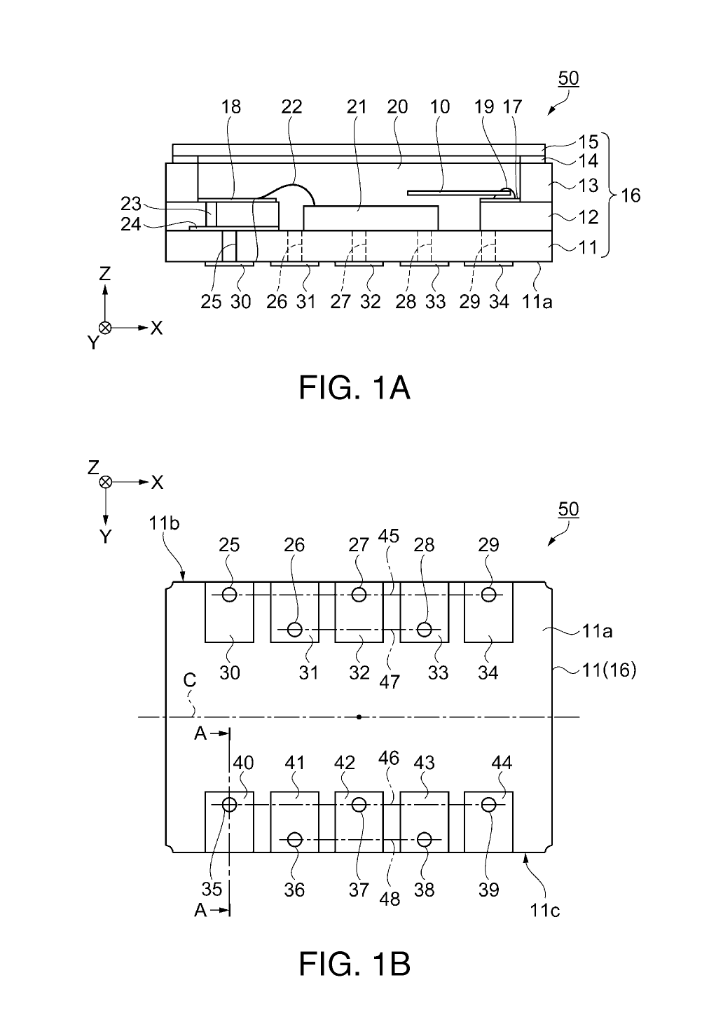

An electronic component according to the first embodiment of the invention will be explained using FIGS. 1A and 1B. FIGS. 1A and 1B are diagrams schematically showing the electronic component according to the first embodiment of the invention, wherein FIG. 1A is a front cross-sectional view, and FIG. 1B is a bottom view of a substrate viewed from the front. It should be noted that in the following explanation, the explanation will be presented citing an oscillator equipped with a resonator element using a quartz crystal as an example of the electronic component according to the first embodiment.

### Oscillator

The oscillator 50 as the electronic component according to the first embodiment shown in FIGS. 1A and 1B includes a resonator element 10, a circuit element 21 having at least a function of driving the resonator element 10, and a package 16 for housing the resonator element 10 and the circuit element 21. Hereinafter, the resonator element 10, the circuit element 21, and the package 16 will sequentially be explained in detail.

### Resonator Element

In the resonator element 10 according to the present embodiment, there is used an AT-cut crystal substrate (a piezoelectric substrate) formed of a quartz crystal as an example of the piezoelectric material. The piezoelectric material such as a quartz crystal belongs to a trigonal system, and has the crystal axes X, Y, and Z perpendicular to each other. The X axis, the Y axis, and the Z axis are called an electrical axis, a mechanical axis, and an optical axis, respectively. Further, among the quartz crystal substrates, a plate carved out from the quartz crystal along a plane obtained by rotating the X-Z plane as much as a predetermined angle θ around the X axis is used as the resonator element 10. For example, in the case of the AT-cut quartz crystal substrate, the angle θ is about 35° 15′. It should be noted that the Y axis and the Z axis are also rotated as much as the angle θ around the X axis to thereby obtain the Y′ axis and the Z′ axis. Therefore, the AT-cut quartz crystal substrate has the crystal axes X, Y′, and Z′ perpendicular to each other. In the AT-cut quartz crystal substrate, the thickness direction is the Y′-axis direction, the principal surface is the X-Z′ plane (the plane including the X axis and the Z′ axis) perpendicular to the Y′ axis, and the thickness-shear vibration is excited as the principal vibration. By processing the AT-cut quartz crystal substrate, the piezoelectric substrate as a raw plate of the resonator element 10 can be obtained. In other words, assuming that in the orthogonal coordinate system constituted by the X axis (the electrical axis), the Y axis (the mechanical axis), and the Z axis (the optical axis), the axis obtained by tilting the Z axis toward the −Y direction of the Y axis around the X axis is the Z′ axis, and the axis obtained by tilting the Y axis toward the +Z direction of the Z axis around the X axis is the Y′ axis, the piezoelectric substrate is formed of the AT-cut quartz crystal substrate constituted by the planes parallel to the X axis and the Z′ axis and having the thickness in a direction parallel to the Y′ axis.

It should be noted that the quartz crystal substrate according to the invention is not limited to the AT-cut substrate with the angle θ roughly equal to 35° 15′, but other piezoelectric substrates such as an SC-cut substrate or a BT-cut substrate for exciting the thickness-shear vibration can also be adopted. There can also be used, for example, a so-called double-rotation-cut quartz crystal substrate having a side parallel to an X′ axis set by rotating the X axis clockwise as much as an angle φ, which is no smaller than 3° and no larger than 30°, around the Z axis assuming that the electrical axis of the quartz crystal is the X axis, the mechanical axis is the Y axis, and the optical axis is the Z axis, and having a side parallel to a Z′ axis obtained by rotating the Z axis clockwise around the X′ axis described above as much as an angle ψ, which is no smaller than 33° and no larger than 36°. On this occasion, in the case of arranging that the angle φ is about 22° and the angle ψ is about 34°, the SC-cut quartz crystal substrate is obtained. Further, the quartz crystal substrate is not limited to the above, but substrates formed to have other cutting angles can also be used. There can also be adopted, for example, a tuning-fork crystal resonator element formed using a so-called Z-cut quartz crystal substrate, which has a predetermined rotational angle with respect to the X axis, as a wafer. Further, a sensor element using other wafers can also be adopted.

In the resonator element 10 according to the present embodiment, a rectangular element piece obtained by dividing the AT-cut quartz crystal substrate described above is used. A variety of electrodes such as excitation electrodes disposed on both of obverse and reverse surfaces, connection electrodes to be connected to other electrodes, and extraction electrodes for connecting the excitation electrodes and the connection electrodes are provided to the element piece, but are not shown in the drawing.

### Package

The package 16 shown in FIGS. 1A and 1B includes a substrate 11, a first side wall 12 as a first side wall layer having a frame-like shape and disposed on the obverse peripheral edge portion of the substrate 11, a second side wall 13 as a second side wall layer having a frame-like shape and disposed on the upper surface of the first side wall 12, a seam ring 14 as a bonding material disposed on the upper surface of the second side wall 13, and a lid 15 as a lid member bonded to the second side wall 13 via the seam ring 14. The package 16 has a function as a housing container for housing the resonator element 10, the circuit element 21, and so on. It should be noted that it is also possible to adopt a configuration in which a plate-like substrate having the same shape as the substrate 11 in a plan view is further disposed on the obverse side of the substrate 11 to form a laminate structure. Further, it is also possible to adopt a configuration in which the frame-like side wall disposed on the obverse peripheral edge of the obverse side of the substrate 11 is eliminated.

As shown in FIGS. 1A and 1B, the package 16 has a recessed section (an internal space 20) opening in an upper surface. The opening of the recessed section is covered by the lid 15 bonded to the second side wall 13 via the seam ring 14 as the bonding material. Thus, there is formed the internal space 20 sealed by covering the opening of the recessed section of the package 16. The inner pressure of the internal space 20 thus sealed can be set to a desired pressure. By, for example, filling the internal space 20 with a nitrogen gas to have the atmospheric pressure, or by producing a vacuum state (the state of a space filled with a gas at a pressure (lower than 1×10⁵ Pa through 1×10⁻¹⁰ Pa (JIS Z 8126-1: 1999)) lower than the normal atmospheric pressure) in the internal space 20, it is possible to continue a more stable vibration of the resonator element 10. It should be noted that the internal space 20 of the present embodiment is set to the vacuum described above.

The first side wall 12 and the second side wall 13 having the frame-like shape are each disposed to have a roughly rectangular rim-like shape, and in other words, the opening shape of the opening in the upper surface of the recessed section described above is formed to be the roughly rectangular shape. The first side wall 12 has an inner end “on the center of the package 16 side of,” in other words “inside” the second side wall 13, and includes a part forming a step in the recessed section. The step formed by the first side wall 12 is provided with PAD electrodes 18, connection terminals 17, and so on. The recessed section, which is surrounded by the substrate 11 having the plate-like shape, and the first side wall 12 and the second side wall 13 each having the frame-like shape, forms the internal space (the housing space) 20 for housing the resonator element 10, the circuit element 21, and so on. On the upper surface of the second side wall 13 having the frame-like shape, there is disposed the seam ring 14 formed of an alloy such as Kovar. The seam ring 14 has a function as the bonding material between the lid 15 and the second side wall 13, and is disposed along the upper surface of the second side wall 13 so as to have a frame-like shape (a roughly rectangular rim-like shape).

The package 16 is formed of a material having a thermal expansion coefficient equal or as close as possible to the thermal expansion coefficient of the resonator element 10 and the lid 15, and ceramic is used as the material in the present embodiment. The package 16 is formed by stacking and then calcining green sheets having been formed to have predetermined shapes. It should be noted that the green sheets are each a material obtained by forming a mixture, which is generated by, for example, dispersing ceramic powder in a predetermined solution and then adding a binder, to have a sheet-like shape.

The substrate 11 forming the bottom section of the package 16 is provided with a wiring electrode 24, and the step of the first side wall 12 is provided with the PAD electrodes 18, the connection terminals 17, and so on. The wiring electrode 24, the PAD electrodes 18, and the connection terminals 17 are each formed by forming the necessary shape using, for example, an electrically-conductive paste made of a silver-palladium alloy or the like, or tungsten metalizing, then performing a calcination treatment, and then plating the result with nickel (Ni), gold (Au), silver (Ag), or the like. In the present embodiment, two connection terminals 17 are disposed so as to be connected to connection electrodes (not shown) of the resonator element 10, and are electrically connected to any of the PAD electrodes 18. The PAD electrodes 18 are electrically connected to any of external connection terminals 30 through 34, and 40 through 44 via a connection electrode 23 penetrating the first side wall 12, the wiring electrode 24, and connection electrodes 25 through 29, and 35 through 39 penetrating the substrate 11. It should be noted that it is also possible to adopt a laminate structure of further disposing a substrate, which has the same plate-like shape as the substrate 11 and is provided with connection electrodes disposed at an area different in a plan view from the area of the connection electrodes 25 through 29, and 35 through 39 penetrating the substrate 11, on the obverse side of the substrate 11, and to adopt a configuration of forming the first side wall 12 on the surface of the laminate structure. Further, it is also possible to adopt a laminate structure of further disposing a substrate, which has the same plate-like shape as the substrate 11 and is provided with connection electrodes disposed at an area different in a plan view from the area of the connection electrodes 25 through 29, and 35 through 39 penetrating the substrate 11, on the obverse side of the substrate 11, and to adopt a configuration of forming the seam ring 14 on the surface of the laminate structure.

The resonator element 10 is bonded to the connection terminals 17 disposed on the step so as to be provided with electrical connection using a bonding material such as an electrically-conductive adhesive 19. Further, the later-described circuit element 21 is bonded to the surface of the substrate 11 with an adhesive (not shown) or the like.

Here, the arrangement of the external connection terminals 30 through 34, and 40 through 44 disposed on the reverse side 11a (the bottom surface of the package 16) of the substrate 11 constituting the package 16, and the connection electrodes 25 through 29, and 35 through 39 connected to the external connection terminals 30 through 34, and 40 through 44 will be explained.

The external connection terminals 30 through 34, and 40 through 44 are located on both sides of a center line C in the Y direction of the substrate 11 shown in the drawing, and are arranged in lines along the edges of the substrate 11. In a detailed description, on one side (outer peripheral side) 11b side of the substrate 11 along the X direction shown in the drawing, there are disposed the five external connection terminals 30, 31, 32, 33, and 34. The external connection terminals 30, 31, 32, 33, and 34 are each disposed from the one side 11b of the substrate 11 toward the center line C having a predetermined width. In other words, the external connection terminals 30, 31, 32, 33, and 34 are each disposed so as to have internal contact with the one side (outer peripheral side) 11b of the substrate 11. Further, on the other side (outer peripheral side) 11c (the side on the opposite side across the center line C) side of the substrate 11 along the X direction shown in the drawing, there are disposed the five external connection terminals 40, 41, 42, 43, and 44. In other words, the external connection terminals 40, 41, 42, 43, and 44 are each disposed so as to have internal contact with the other side (outer peripheral side) 11c of the substrate 11. The external connection terminals 40, 41, 42, 43, and 44 are each disposed from the other side 11c of the substrate 11 toward the center line C having a predetermined width. In other words, the external connection terminals 30, 31, 32, 33, and 34 and the external connection terminals 40, 41, 42, 43, and 44 are disposed roughly symmetrically about the center line C.

Since the external connection terminals 30 through 34 have internal contact with the one side (outer peripheral side) 11b of the substrate 11, and the external connection terminals 40 through 44 are disposed so as to have internal contact with the other side (outer peripheral side) 11c as described above, the surface area of each of the external connection terminals 30 through 34, and 40 through 44 can be enlarged. Thus, the bonding area with the mounting board can be enlarged, and thus, the bonding strength can be increased. Further, since the bonding area with the mounting board is enlarged, the strength of the substrate 11 constituting the package 16 can also be increased.

It should be noted that although in the present embodiment, there is used the example of disposing the external connection terminals 30, 31, 32, 33, and 34 and the external connection terminals 40, 41, 42, 43, and 44 five by five roughly symmetrically about the center line C, the arrangement and the number of the external connection terminals are not limited to those of the example. The external connection terminals 30 through 34, and 40 through 44 are each formed by forming the necessary shape using, for example, an electrically-conductive paste made of a silver-palladium alloy or the like, or tungsten metalizing, then performing a calcination treatment, and then plating the result with nickel (Ni), gold (Au), silver (Ag), or the like.

The connection electrodes 25 through 29, and 35 through 39 are respectively connected to the external connection terminals 30 through 34, and 40 through 44. In a detailed description, the connection electrode 25 is connected to the external connection terminal 30, the connection electrode 26 is connected to the external connection terminal 31, and thereafter, the connection is sequentially established until the connection electrode 29 is connected to the external connection terminal 34. The same applies to the connection electrodes and the external connection terminals arranged on the opposite side. The connection electrode 35 is connected to the external connection terminal 40, the connection electrode 36 is connected to the external connection terminal 41, and thereafter, the connection is sequentially established until the connection electrode 39 is connected to the external connection terminal 44. It should be noted that it is preferable that the connection electrodes 25 through 29, and 35 through 39 are disposed inside the respective external connection terminals 30 through 34, and 40 through 44. By disposing the connection electrodes 25 through 29, and 35 through 39 inside the respective external connection terminals 30 through 34, and 40 through 44 as described above, the portions of the package 16 (the substrate 11), which are provided with the respective connecting electrodes 25 through 29, and 35 through 39, and are therefore low in strength, are included in the bonding material when mounting the package 16. Therefore, the bonding material acts as a strength-reinforcing material, and in other words, the bonding material increases the strength of the package 16 (the substrate 11). Thus, it becomes possible to prevent the breakage of the package 16 (the substrate 11) due to a stress after mounting.

The arrangement of the connection electrodes 25 through 29, and 35 through 39 will be explained. Firstly, the connection electrodes 25, 26, 27, 28, and 29 disposed on the one side 11b side of the substrate 11 will be explained. Here, the explanation will be presented as an example assuming that the connection electrode 25 is a first connection electrode, the connection electrode 26 is a second connection electrode, and the connection electrode 27 is a third connection electrode. It should be noted that the connection electrode 25 as the first connection electrode is provided with a first hole extending from one surface (the reverse side 11a) of the substrate 11 to the other surface, and a conductor disposed inside the first hole although not shown in the drawings. Similarly, the connection electrode 26 as the second connection electrode is provided with a second hole extending from the one surface (the reverse side 11a) of the substrate 11 to the other surface, and a conductor disposed inside the second hole although not shown in the drawings. Similarly, the connection electrode 27 as the third connection electrode is provided with a third hole extending from the one surface (the reverse side 11a) of the substrate 11 to the other surface, and a conductor disposed inside the third hole although not shown in the drawings. Further, other connection electrodes each have substantially the same configuration.

These three connection electrodes 25, 26, and 27 are arranged as follows. The center of the connection electrode 26 as the second connection electrode does not exist on an imaginary line 45 connecting the center of the connection electrode 25 as the first connection electrode and the center of the connection electrode 27 as the third connection electrode to each other, but is disposed at a position (a position shifted toward the center line C in the present embodiment) out of the imaginary line 45.

Further, the explanation will be presented assuming that the connection electrode 27 is a second connection electrode, the connection electrode 26 is a first connection electrode, and the connection electrode 28 is a third connection electrode as another example. These three connection electrodes 26, 27, and 28 are arranged as follows. The center of the connection electrode 27 as the second connection electrode does not exist on an imaginary line 47 connecting the center of the connection electrode 26 as the first connection electrode and the center of the connection electrode 28 as the third connection electrode to each other, but is disposed at a position (a position shifted toward the one side 11b of the substrate 11 in the present embodiment) out of the imaginary line 47.

As described above, the connection electrodes 25 through 29 are arranged so that the connection electrodes adjacent to each other are shifted from each other in a direction intersecting with the arranging direction (in the X direction in the present embodiment) in a so-called zigzag manner. In other words, the connection electrodes 25 through 29 are arranged so as not to form a straight line (an arrangement of so-called perforations arranged in a straight line).

Then, the connection electrodes 35, 36, 37, 38, and 39 disposed on the other side 11c of the substrate 11 will be explained. Here, the explanation will be presented as an example assuming that the connection electrode 35 is a first connection electrode, the connection electrode 36 is a second connection electrode, and the connection electrode 37 is a third connection electrode. It should be noted that the connection electrode 35 as the first connection electrode is provided with a first hole extending from one surface (the reverse side 11a) of the substrate 11 to the other surface, and a conductor disposed inside the first hole although not shown in the drawings. Similarly, the connection electrode 36 as the second connection electrode is provided with a second hole extending from the one surface (the reverse side 11a) of the substrate 11 to the other surface, and a conductor disposed inside the second hole although not shown in the drawings. Similarly, the connection electrode 37 as the third connection electrode is provided with a third hole extending from the one surface (the reverse side 11a) of the substrate 11 to the other surface, and a conductor disposed inside the third hole although not shown in the drawings. Further, other connection electrodes each have substantially the same configuration.

These three connection electrodes 35, 36, and 37 are arranged as follows. The center of the connection electrode 36 as the second connection electrode does not exist on an imaginary line 46 connecting the center of the connection electrode 35 as the first connection electrode and the center of the connection electrode 37 as the third connection electrode to each other, but is disposed at a position (a position shifted toward the other side 11c of the substrate 11 in the present embodiment) out of the imaginary line 46.

Further, the explanation will be presented assuming that the connection electrode 37 is the second connection electrode, the connection electrode 36 is the first connection electrode, and the connection electrode 38 is the third connection electrode as another example. These three connection electrodes 36, 37, and 38 are arranged as follows. The center of the connection electrode 37 as the second connection electrode does not exist on an imaginary line 48 connecting the center of the connection electrode 36 as the first connection electrode and the center of the connection electrode 38 as the third connection electrode to each other, but is disposed at a position (a position shifted toward the center line C in the present embodiment) out of the imaginary line 48.

As described above, the connection electrodes 35 through 39 are arranged so that the connection electrodes adjacent to each other are shifted from each other in a direction intersecting with the arranging direction (in the X direction in the present embodiment) in a so-called zigzag manner. In other words, the connection electrodes 35 through 39 are arranged so as not to form a straight line (an arrangement of so-called perforations arranged in a straight line).

By arranging the connection electrodes 25 through 29, and 35 through 39 as described above, the connection electrodes 35 through 39 fail to be arranged in a straight line. Thus, the low-strength part of the substrate 11 caused by the connection electrodes 25 through 29, and 35 through 39 arranged in a straight line is eliminated, and thus the strength of the package 16 can be inhibited from deteriorating.

Further, the connection electrodes 25 through 29 are arranged along the one side 11b of the substrate 11 (in the X direction shown in the drawing), and the connection electrodes 35 through 39 are arranged along the other side 11c of the substrate 11 (in the X direction shown in the drawing). Thus, the connection electrodes 25 through 29, and 35 through 39 can efficiently be arranged, and it becomes possible to reduce the size of the arrangement space of the connection electrodes 25 through 29, and 35 through 39.

Further, although it is preferable to dispose the connection electrodes 25 through 29 on the one side 11b side of the substrate 11 and the connection electrodes 35 through 39 on the other side 11c side asymmetrically about the center line C of the substrate 11 as in the arrangement example shown in FIG. 1B, it is also possible to arrange the connection electrodes 25 through 29 and the connection electrodes 35 through 39 symmetrically about the center line C. In particular, by disposing the connection electrodes 25 through 29 and the connection electrodes 35 through 39 asymmetrically about the center line C, it is possible to make the distances between the respective connection electrodes different from each other, and thus, it becomes possible to achieve decentralization of the stress or the like. Thus, the strength of the substrate can be increased.

The lid 15 is a plate-like member, and is bonded to the periphery of the opening of the recessed section opening in the upper surface of the package 16 using, for example, a seam welding method so as to cover the opening of the recessed section. The lid 15 according to the present embodiment has a plate-like shape, and is therefore easy to be formed, and is further superior in stability of the shape. Further, a Kovar plate is used as the lid 15 of the present embodiment. By using the Kovar plate as the lid 15, the seam ring 14 formed of Kovar and the lid 15 are melted in the same molten state in the sealing process, and further, the alloying occurs easily. Therefore, sealing can easily and reliably be performed. It should be noted that it is also possible to use a plate made of another material as the lid 15 instead of Kovar, a metal material such as 42Alloy or stainless steel, the same material as the second side wall 13 of the package 16, and so on can be used.

### Circuit Element

The circuit element 21 is disposed on the substrate 11, and is connected to the substrate 11 with a resin adhesive or the like. The circuit element 21 is provided with, for example, an oscillator circuit for oscillating the resonator element 10. On an active surface of the circuit element 21, there are disposed electrode pads not shown, and the electrode pads and the PAD electrodes 18 provided to the step of the first side wall 12 constituting the package 16 are connected to each other with metal wiring (bonding wires) 22 so as to achieve electrical conduction therebetween.

The oscillator 50 described above is provided with the connection electrode 26 as the second connection electrode connected to either one of the external connection terminals 30 through 34 disposed on the one side 11b side of one surface (the reverse side 11a) of the substrate 11 constituting the package 16, and the connection electrode 25 as the first connection electrode and the connection electrode 27 as the third connection electrode each adjacent to the connection electrode 26. Further, the center of the connection electrode 26 does not exist on the imaginary line 45 connecting the center of the connection electrode 25 and the center of the connection electrode 27 to each other, but is disposed at a position (a position shifted toward the center line C) out of the imaginary line 45.

As described above, according to the oscillator 50 as the electronic component related to the first embodiment, the three connection electrodes 25, 26, and 27 adjacent to each other fail to be arranged in a straight line. Further, the other connection electrodes 28, 29 thus disposed and the connection electrodes 35 through 39 on the other side 11c side have substantially the same arrangement. Thus, the part causing the decrease in strength of the package 16 (the substrate 11) due to the connection electrodes 25 through 29, and 35 through 39 arranged side by side in a straight line is eliminated, and it becomes possible to inhibit the strength of the package from deteriorating to thereby increase the strength of the package 16 (the substrate 11).

According to the oscillator 50 using such a package 16 as described above, even in the case in which the stress caused by the deformation of the mounting board on which the oscillator 50 is mounted is applied to the package 16, a problem such as crack can be inhibited. Further, it is possible to prevent the breakage or occurrence of a microscopic crack due to the flexural stress applied in breaking off the package (a break process) when segmenting the package 16 from a sheet of the packages 16 processed as a sheet in the manufacturing process of the package 16. Therefore, by using such a package 16 as described above, it becomes possible to provide the oscillator 50 with the strength of the package 16 (the substrate 11) enhanced.

### Second Embodiment

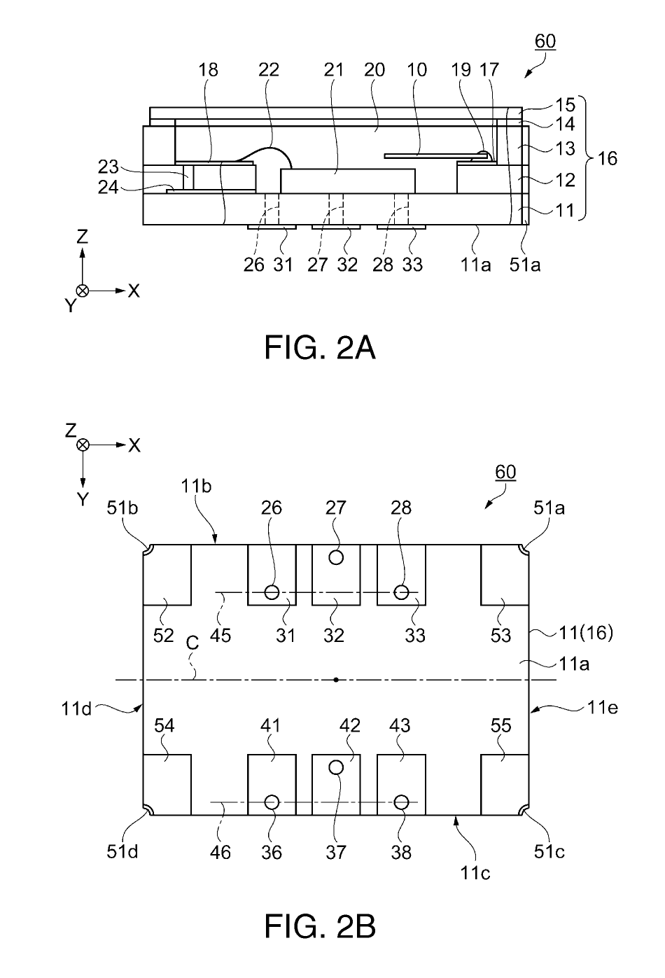

Then, an electronic component according to a second embodiment of the invention will be explained using FIGS. 2A and 2B. FIGS. 2A and 2B are diagrams schematically showing the electronic component according to the second embodiment of the invention, wherein FIG. 2A is a front view, and FIG. 2B is a bottom view of a substrate viewed from the front. It should be noted that in FIG. 2A, the right side of the break line shown on the right side of the drawing is a front view instead of a cross-sectional view, and the right side and the left side of the break line shown on the left side of the drawing are cross-sectional views showing respective cross-sectional surfaces different in position from each other. Further, in the following explanation, the explanation will be presented citing an oscillator equipped with a resonator element using a quartz crystal as an example of the electronic component according to the second embodiment.

### Oscillator

The oscillator 60 as the electronic component according to the second embodiment shown in FIGS. 2A and 2B includes the resonator element 10, the circuit element 21 having at least a function of driving the resonator element 10, and the package 16 for housing the resonator element 10 and the circuit element 21. The oscillator 60 as the electronic component according to the second embodiment is different from the oscillator 50 as the electronic component according to the first embodiment described above in the configuration of the external connection terminals and the connection electrodes. The resonator element 10, the circuit element 21, and the seam ring 14 and the lid 15 constituting the package 16 have substantially the same configuration, and are therefore denoted with the same reference symbols, and the explanation thereof will be omitted, and the different constituents will be explained in detail.

### Package

The package 16 shown in FIGS. 2A and 2B includes the substrate 11, the first side wall 12 as the first side wall layer having a frame-like shape and disposed on the obverse peripheral edge portion of the substrate 11, the second side wall 13 as the second side wall layer having a frame-like shape and disposed on the upper surface of the first side wall 12, the seam ring 14 as the bonding material disposed on the upper surface of the second side wall 13, and the lid 15 as the lid member bonded to the second side wall 13 via the seam ring 14. As described above, the package 16 has substantially the same configuration as that of the first embodiment, but is provided with lateral electrodes 51a, 51b, 51c, and 51d disposed on the four corners. It should be noted that the package 16 has a function as a housing container for housing the resonator element 10, the circuit element 21, and so on similarly to the case of the first embodiment.

Hereinafter, the package 16 will be explained focusing mainly on the lateral electrodes 51a, 51b, 51c, and 51d, the external connection terminals 31, 32, 33, 52, 53, 41, 42, 43, 54, and 55, and the connection electrodes 26, 27, 28, 36, 37, and 38 different from the first embodiment described above.

The package 16 has the recessed section (the internal space 20) opening in the upper surface. The opening of the recessed section is covered by the lid 15 bonded to the second side wall 13 via the seam ring 14 as the bonding material. Thus, there is formed the internal space 20 sealed by covering the opening of the recessed section of the package 16.

The first side wall 12 and the second side wall 13 having the frame-like shape are each disposed to have a roughly rectangular rim-like shape, and in other words, the opening shape of the opening in the upper surface of the recessed section described above is formed to be the roughly rectangular shape. The first side wall 12 has an inner end “on the center of the package 16 side of,” in other words “inside” the second side wall 13, and includes a part forming a step in the recessed section. The step formed by the first side wall 12 is provided with the PAD electrodes 18, the connection terminals 17, and so on. The recessed section, which is surrounded by the substrate 11 having the plate-like shape, and the first side wall 12 and the second side wall 13 each having the frame-like shape, forms the internal space (the housing space) 20 for housing the resonator element 10, the circuit element 21, and so on. On the upper surface of the second side wall 13 having the frame-like shape, there is disposed the seam ring 14 formed of an alloy such as Kovar. The seam ring 14 has a function as the bonding material between the lid 15 and the second side wall 13, and is disposed along the upper surface of the second side wall 13 so as to have a frame-like shape (a roughly rectangular rim-like shape).

On the four corners of the substrate 11, the first side wall 12, and the second side wall 13 stacked on each other so as to form the recessed section opening in the upper surface, there are disposed depressed sections each depressed so as to have an arc-like shape. On the respective surfaces of the four depressed sections, there are disposed lateral electrodes 51a, 51b, 51c, and 51d. The lateral electrodes 51a, 51b, 51c, and 51d are also called castellations, and are each formed by forming the necessary shape using, for example, an electrically-conductive paste made of a silver-palladium alloy or the like, or tungsten metalizing, then performing a calcination treatment, and then plating the result with nickel (Ni), gold (Au), silver (Ag), or the like. The lateral electrodes 51a, 51b, 51c, and 51d are electrically connected to the wiring electrode 24, the plurality of PAD electrodes 18, connection terminals, and so on described later (not shown). It should be noted that the material of the package 16 is substantially the same as in the first embodiment, and therefore, the explanations thereof will be omitted. Further, the shape of the depressed sections on which the lateral electrodes 51a, 51b, 51c, and 51d are respectively disposed is not limited to the arc-like shape, but can be any shape providing the electrode can be formed thereon.

The substrate 11 forming the bottom section of the package 16 is provided with the wiring electrode 24, and the step of the first side wall 12 is provided with the plurality of PAD electrodes 18, the connection terminals 17, and so on. The wiring electrode 24, the PAD electrodes 18, and the connection terminals 17 are each formed by forming the necessary shape using, for example, an electrically-conductive paste made of a silver-palladium alloy or the like, or tungsten metalizing, then performing a calcination treatment, and then plating the result with nickel (Ni), gold (Au), silver (Ag), or the like. In the present embodiment, two connection terminals 17 are disposed so as to be connected to connection electrodes (not shown) of the resonator element 10, and are electrically connected to any of the PAD electrodes 18. The PAD electrodes 18 are electrically connected to any of the external connection terminals 31, 32, 33, 52, 53, 41, 42, 43, 54, and 55 via a connection electrode 23 penetrating the first side wall 12, the wiring electrode 24, connection electrodes 26, 27, 28, 36, 37, and 38 penetrating the substrate 11, and the lateral electrodes 51a, 51b, 51c, and 51d. It should be noted that connections between some of the constituents are omitted.

Here, the arrangement of the external connection terminals 31, 32, 33, 52, 53, 41, 42, 43, 54, and 55 disposed on the reverse side 11a (the bottom surface of the package 16) of the substrate 11 constituting the package 16, and the connection electrodes 26, 27, 28, 36, 37, and 38 and the lateral electrodes 51a, 51b, 51c, and 51d connected to the external connection terminals 31, 32, 33, 52, 53, 41, 42, 43, 54, and 55 will be explained.

The external connection terminals 31, 32, and 33 and the external connection terminals 41, 42, and 43 are located on both sides of the center line C in the Y direction of the reverse side 11a of the substrate 11 shown in the drawing, and are arranged in lines along the sides (outer peripheral sides) of the substrate 11. In a detailed description, on one side (an outer peripheral side) 11b side of the substrate 11 along the X direction shown in the drawing, there are disposed three external connection terminals 31, 32, and 33. The external connection terminals 31, 32, and 33 are each disposed from one side 11b of the substrate 11 toward the center line C having a predetermined width. Further, on the other side (outer peripheral side) 11c (the side on the opposite side across the center line C) side of the substrate 11 along the X direction shown in the drawing, there are disposed the three external connection terminals 41, 42, and 43. The external connection terminals 41, 42, and 43 are each disposed from the other side 11c of the substrate 11 toward the center line C having a predetermined width. In other words, the external connection terminals 31, 32, and 33 and the external connection terminals 41, 42, and 43 are disposed roughly symmetrically about the center line C.

Further, in the areas respectively including the four corners of the reverse side 11a, there are disposed the external connection terminals 52, 53, 54, and 55 connected to the lateral electrodes 51a, 51b, 51c, and 51d disposed on the depressed sections as the lateral surfaces connecting the one surface (the reverse side 11a) of the substrate 11 and the other surface to each other, respectively. In a detailed description of the arrangement, the external connection terminal 52 is disposed on the −X direction side of the external connection terminal 31 so as to reach the one side 11b and a side 11d intersecting with the one side 11b, and is connected to the lateral electrode 51b. Further, the external connection terminal 53 is disposed on the +X direction side of the external connection terminal 33 so as to reach the one side 11b and a side 11e intersecting with the one side 11b, and is connected to the lateral electrode 51a. Further, the external connection terminal 54 is disposed on the −X direction side of the external connection terminal 41 so as to reach the other side 11c and the side 11d, and is connected to the lateral electrode 51d. Further, the external connection terminal 55 is disposed on the +X direction side of the external connection terminal 43 so as to reach the other side 11c and the side 11e, and is connected to the lateral electrode 51c.

Since each of the external connection terminals 52, 53, 54, and 55 is disposed so as to reach the two outer peripheral sides among the outer peripheral sides of the substrate 11, the surface area of each of the external connection terminals 52, 53, 54, and 55 can be increased. Thus, the bonding area with the mounting board can be enlarged, and thus, the bonding strength can be increased. Further, since the bonding area with the mounting board is enlarged, the strength of the substrate 11 constituting the package 16 can also be increased.

It should be noted that although in the present embodiment, there is used the example of disposing the external connection terminals 31, 32, 33, 52, and 53 and the external connection terminals 41, 42, 43, 54, and 55 five by five on the both sides with reference to the center line C, the arrangement and the number of the external connection terminals are not limited to those of the example. The external connection terminals 31, 32, 33, 41, 42, 43, 52, 53, 54, and 55 are each formed by forming the necessary shape using, for example, an electrically-conductive paste made of a silver-palladium alloy or the like, or tungsten metalizing, then performing a calcination treatment, and then plating the result with nickel (Ni), gold (Au), silver (Ag), or the like.

The connection electrodes 26, 27, and 28 are respectively connected to the external connection terminals 31, 32, and 33. Further, the connection electrodes 36, 37, and 38 disposed on the opposite side are respectively connected to the external connection terminals 41, 42, and 43. In a detailed description, the connection electrode 26 is connected to the external connection terminal 31, the connection electrode 27 is connected to the external connection terminal 32, and the connection electrode 28 is connected to the external connection terminal 33. The same applies to the connection electrodes and the external connection terminals arranged on the opposite side. The connection electrode 36 is connected to the external connection terminal 41, the connection electrode 37 is connected to the external connection terminal 42, and the connection electrode 38 is connected to the external connection terminal 43.

The arrangement of the connection electrodes 26, 27, and 28 and the connection electrodes 36, 37, and 38 will be explained. Firstly, the connection electrodes 26, 27, 28 disposed on the one side 11b side of the substrate 11 will be explained. Here, the explanation will be presented as an example assuming that the connection electrode 26 is the first connection electrode, the connection electrode 27 is the second connection electrode, and the connection electrode 28 is the third connection electrode. It should be noted that the connection electrode 26 as the first connection electrode is provided with a first hole extending from one surface (the reverse side 11a) of the substrate 11 to the other surface, and a conductor disposed inside the first hole although not shown in the drawings. Similarly, the connection electrode 27 as the second connection electrode is provided with a second hole extending from the one surface (the reverse side 11a) of the substrate 11 to the other surface, and a conductor disposed inside the second hole although not shown in the drawings. Similarly, the connection electrode 28 as the third connection electrode is provided with a third hole extending from the one surface (the reverse side 11a) of the substrate 11 to the other surface, and a conductor disposed inside the third hole although not shown in the drawings. Further, other connection electrodes each have substantially the same configuration. These three connection electrodes 26, 27, and 28 are arranged as follows. The center of the connection electrode 27 as the second connection electrode does not exist on an imaginary line 45 connecting the center of the connection electrode 26 as the first connection electrode and the center of the connection electrode 28 as the third connection electrode, but is disposed at a position (a position shifted toward the one side 11b of the substrate 11 in the present embodiment) out of the imaginary line 45.

Further, the explanation will be presented assuming that the connection electrode 37 is the second connection electrode, the connection electrode 36 is the first connection electrode, and the connection electrode 38 is the third connection electrode on the other side 11c side of the substrate 11. These three connection electrodes 36, 37, and 38 are arranged as follows. The center of the connection electrode 37 as the second connection electrode does not exist on an imaginary line 46 connecting the center of the connection electrode 36 as the first connection electrode and the center of the connection electrode 38 as the third connection electrode to each other, but is disposed at a position (a position shifted toward the center line C in the present embodiment) out of the imaginary line 46.

As described above, the connection electrodes 26, 27, and 28 and the connection electrodes 36, 37, and 38 are arranged so that the connection electrodes adjacent to each other are shifted from each other in a direction intersecting with the arranging direction (in the X direction in the present embodiment) in a so-called zigzag manner. In other words, the connection electrodes 26, 27, and 28 and the connection electrodes 36, 37, and 38 are each arranged so as not to form a straight line (an arrangement of so-called perforations arranged in a straight line).

By arranging the connection electrodes 26, 27, and 28 and the connection electrodes 36, 37, and 38 as described above, the connection electrodes 26, 27, and 28 and the connection electrodes 36, 37, and 38 each fail to be arranged side by side in a straight line. Thus, the low-strength part of the substrate 11 caused by the connection electrodes 26, 27, and 28 and the connection electrodes 36, 37, and 38 each arranged in a straight line is eliminated, and thus the strength of the package 16 can be inhibited from deteriorating.

Further, the connection electrodes 26, 27, and 28 are arranged along the one side 11b of the substrate 11 (in the X direction shown in the drawing), and the connection electrodes 36, 37, and 38 are arranged along the other side 11c of the substrate 11 (in the X direction shown in the drawing). Thus, the connection electrodes 26, 27, and 28 and the connection electrodes 36, 37, and 38 can efficiently be arranged, and it becomes possible to reduce the size of the arrangement space of the connection electrodes 26, 27, and 28 and the connection electrodes 36, 37, and 38.

Further, although it is preferable to dispose the connection electrodes 26, 27, and 28 on the one side 11b side of the substrate 11 and the connection electrodes 36, 37, and 38 on the other side 11c side asymmetrically about the center line C of the substrate 11 as in the arrangement example shown in FIG. 2B, it is also possible to arrange the connection electrodes 26, 27, and 28 and the connection electrodes 36, 37, and 38 symmetrically about the center line C. In particular, by disposing the connection electrodes 26, 27, and 28 and the connection electrodes 36, 37, and 38 asymmetrically about the center line C, it is possible to make the distances between the respective connection electrodes different from each other, and thus, it becomes possible to achieve decentralization of the stress or the like. Thus, the strength of the substrate can be increased.

Further, according to the configuration of the second embodiment, since the connection electrode is not provided to the external connection terminals 52, 53, 54, and 55 on the four corners, the distances from each of the sides 11b, 11c, 11d, and 11e of the substrate 11 (the package 16) to the connection electrodes are elongated, and thus, it becomes possible to increase the substrate strength.

### Modified Examples of Connection Electrode Arrangement

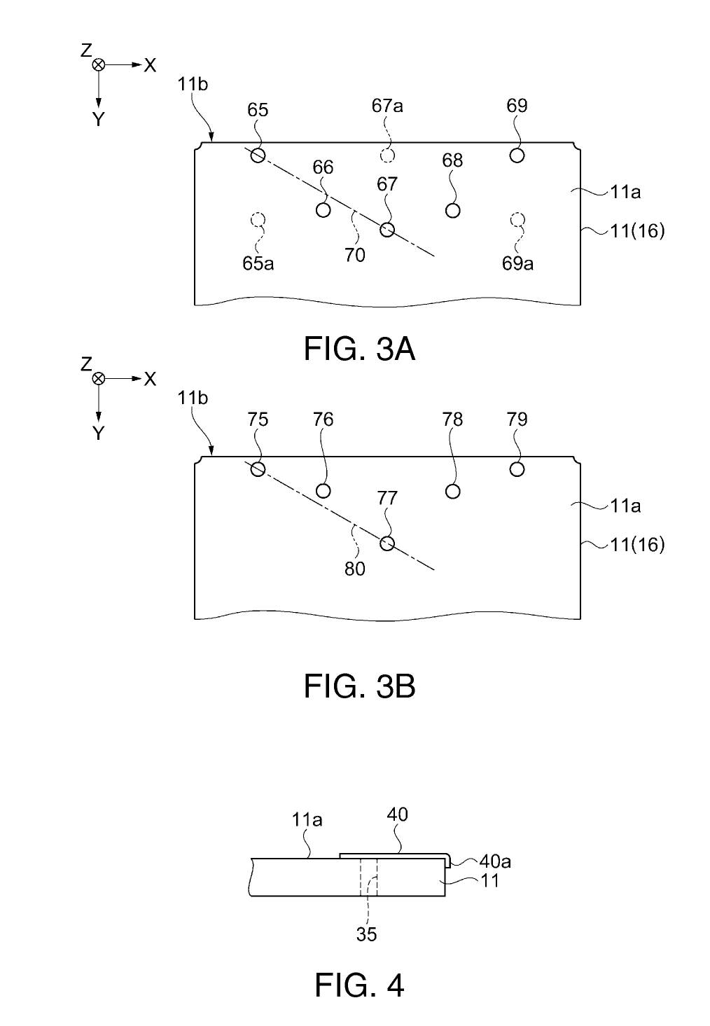

Then, some modified examples of the arrangement of the connection electrodes will be explained using FIGS. 3A and 3B. FIGS. 3A and 3B are each a bottom view of the package showing a modified example of the arrangement of the connection electrodes. Also in the modified examples described below, substantially the same advantage as in the first embodiment and the second embodiment described above can be obtained.

### Modified Example 1

Firstly, the arrangement of the connection electrodes according to modified example 1 will be explained using FIG. 3A. The connection electrodes 65, 66, 67, 68, and 69 of modified example 1 are in an arrangement shaped like a gentle circular arc instead of the zigzag arrangement as in the first and second embodiments described above. The details of the arrangement will be explained below.

The connection electrodes 65, 66, 67, 68, and 69 are arranged in this order from the −X direction side in the drawing. The connection electrode 65 and the connection electrode 69 are disposed near to the one side 11b of the substrate 11, and the connection electrode 67 is disposed far from the one side 11b. The positions in the Y direction of the connection electrode 66 and the connection electrode 68 are intermediate in distance between the positions of the connection electrodes 65, 69 and the position of the connection electrode 67. Here, the explanation will further be presented assuming that the connection electrode 65 is the first connection electrode, the connection electrode 66 is the second connection electrode, and the connection electrode 67 is the third connection electrode. These three connection electrodes 65, 66, and 67 are arranged as follows. The center of the connection electrode 66 as the second connection electrode does not exist on an imaginary line 70 connecting the center of the connection electrode 65 as the first connection electrode and the center of the connection electrode 67 as the third connection electrode to each other, but is disposed at a position out of the imaginary line 70. As described above, the three connection electrodes adjacent to each other are arranged so that the center of the middle connection electrode fail to overlap the imaginary line connecting the centers of the connection electrodes in both ends to each other in a similar manner.

It should be noted that although in modified example 1, the explanation is presented using the example in which the connection electrodes 65, 59 in both ends are arranged near to the one side 11b, it is also possible to adopt the configuration indicated by the dashed-two dotted lines as connection electrodes 65a, 67a, and 69a, in which each connection electrode 65a, 69a as one of the connection electrodes in both ends is disposed far from the one side 11b and the middle connection electrode 67a is disposed near to the one side 11b.

### Modified Example 2

Then, the arrangement of the connection electrodes according to modified example 2 will be explained using FIG. 3B. Connection electrodes 75, 76, 77, 78, and 79 of modified example 2 are disposed at random positions, but do not have a regular arrangement as adopted in the first and second embodiments described above. The details of the arrangement will be explained below.

The connection electrodes 75, 76, 77, 78, and 79 are arranged in this order from the −X direction side in the drawing. The point that the connection electrode 75 and the connection electrode 79 are disposed near to the one side 11b of the substrate 11, and the connection electrode 77 is disposed far from the one side 11b is the same as in modified example 1 described above. The positions in the Y direction of the connection electrode 76 and the connection electrode 78 are intermediate in distance between the positions of the connection electrodes 75, 79 and the position of the connection electrode 77, but are not regularly arranged. Here, the explanation will further be presented assuming that the connection electrode 75 is the first connection electrode, the connection electrode 76 is the second connection electrode, and the connection electrode 77 is the third connection electrode. These three connection electrodes 75, 76, and 77 are arranged as follows. The center of the connection electrode 76 as the second connection electrode does not exist on an imaginary line 80 connecting the center of the connection electrode 75 as the first connection electrode and the center of the connection electrode 77 as the third connection electrode to each other, but is disposed at a position shifted toward the −Y direction in the drawing, which is out of the imaginary line 80. As described above, the three connection electrodes adjacent to each other are arranged so that the center of the middle connection electrode fail to overlap the imaginary line connecting the centers of the connection electrodes in both ends to each other in a similar manner.

It should be noted that the arrangement of the connection electrodes explained in the above description is illustrative only. Any arrangement can be adopted as the arrangement of the connection electrodes providing the three connection electrodes adjacent to each other are arranged so that the center of the middle connection electrode fail to overlap the imaginary line connecting the centers of the connection electrodes in both ends to each other.

Further, it is also possible for the external connection terminal 40 to be provided with a lateral portion 40a at least partially covering the reverse side 11a and the side surface of the substrate 11. Since the lateral portion 40a is provided, there is obtained an advantage that, for example, a good solder fillet is formed in the mounting process to increase the mounting strength. It should be noted that FIG. 4 shows the cross-sectional view at the same position as the position of the cross-sectional view along the A-A line shown in FIG. 1B.

Further, although in the above description, the ceramic substrate is explained as an example of the constituent material of the package 16, the material is not limited to this example, and it is also possible to use, for example, a quartz crystal substrate, a glass substrate, and a silicon substrate.

Further, although in the above description, the sealing of the package 16 is explained using the configuration of bonding the lid 15 as the lid member to the second side wall 13 via the seam ring 14, the sealing is not limited to this configuration. Any configuration can be adopted providing the airtight sealing can be achieved. There can also be adopted a configuration of, for example, using a metal cap provided with a concave internal space, and bonding the metal cap to the surface of the ceramic substrate using a seam welding process or the like.

Further, although in the above description, the explanation is presented using the oscillator as an example of the electronic component, the electronic component is not limited to this example. The invention can also be applied to, for example, a resonator housing a resonator element, a sensor device housing a sensor element capable of measuring an acceleration, an angular velocity, a pressure, and so on instead of the resonator element, and a semiconductor device housing a circuit element.

### Electronic Apparatus

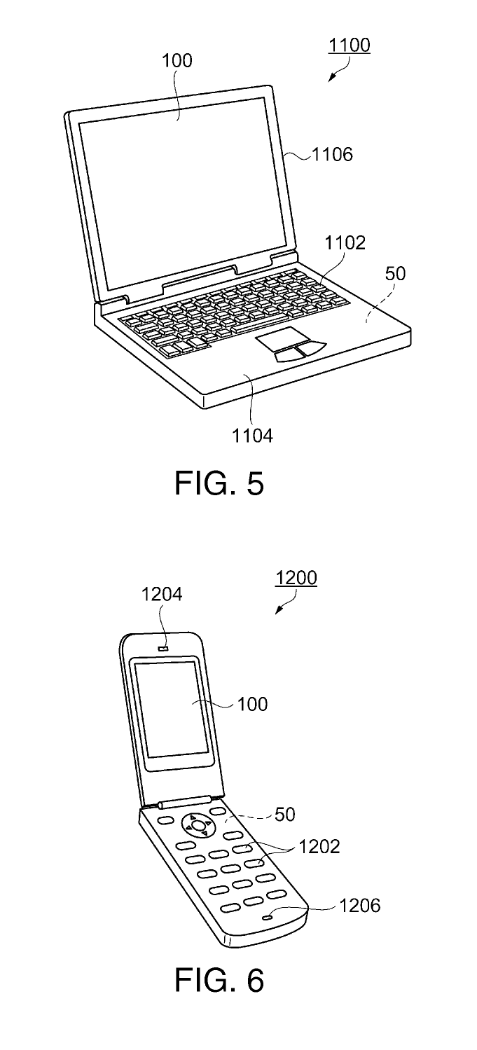

Then, the electronic apparatuses to which the either one of the oscillators 50, 60 as the electronic component according to an embodiment of the invention is applied will be explained in detail with reference to FIGS. 5 through 7. It should be noted that in the explanation, an example of applying the oscillator 50 is described.

FIG. 5 is a perspective view showing a schematic configuration of a mobile type (or a laptop type) personal computer as the electronic apparatus equipped with the oscillator 50 as the electronic component according to an embodiment of the invention. In the drawing, the personal computer 1100 includes a main body section 1104 provided with a keyboard 1102, and a display unit 1106 provided with a display section 100, and the display unit 1106 is pivotally supported with respect to the main body section 1104 via a hinge structure. Such a personal computer 1100 incorporates the oscillator 50 provided with a function as a timing source for signal processing.

FIG. 6 is a perspective view showing a schematic configuration of a cellular phone (including PHS) as the electronic apparatus equipped with the oscillator 50 as the electronic component according to an embodiment of the invention. In this drawing, the cellular phone 1200 is provided with a plurality of operation buttons 1202, an ear piece 1204, and a mouthpiece 1206, and the a display section 100 is disposed between the operation buttons 1202 and the ear piece 1204. Such a cellular phone 1200 incorporates the oscillator 50 provided with a function as a timing source for signal processing.

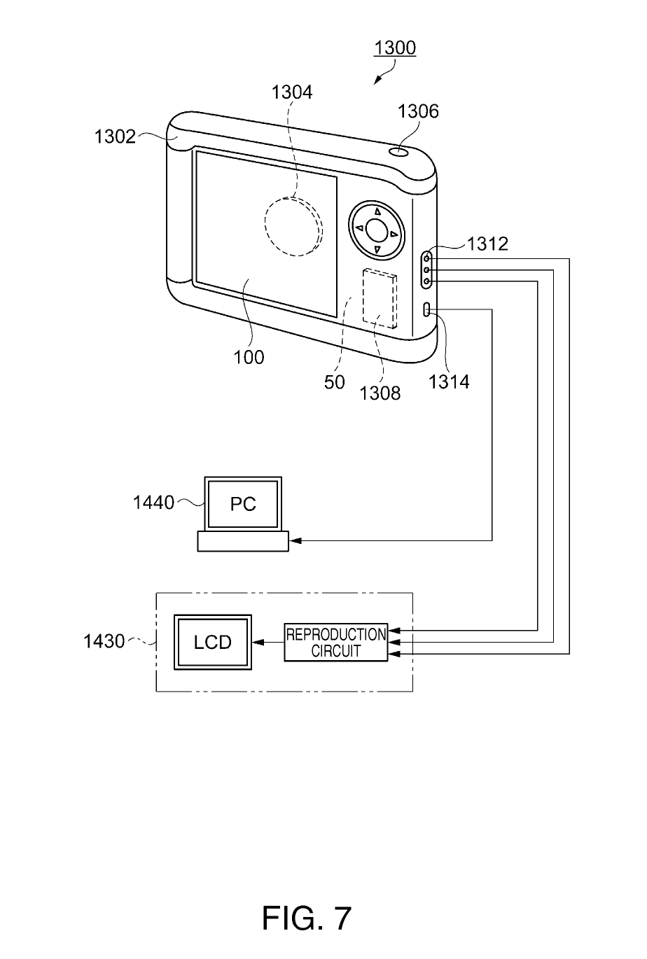

FIG. 7 is a perspective view showing a schematic configuration of a digital still camera as the electronic apparatus equipped with the oscillator 50 as the electronic component according to an embodiment of the invention. It should be noted that the connection with external equipment is also shown briefly in this drawing. Here, the existing film cameras expose a silver salt film to an optical image of an object, while the digital still camera 1300 performs photoelectric conversion on an optical image of an object by an imaging element such as a CCD (a charge coupled device) to generate an imaging signal (an image signal).

A case (a body) 1302 of the digital still camera 1300 is provided with a display section 100 disposed on the back surface of the case 1302 to provide a configuration of performing display in accordance with the imaging signal from the CCD, wherein the display section 100 functions as a viewfinder for displaying the object as an electronic image. Further, the front surface (the reverse side in the drawing) of the case 1302 is provided with a light receiving unit 1304 including an optical lens (an imaging optical system), the CCD, and so on.

When a photographer checks an object image displayed on the display section 100, and then holds down a shutter button 1306, the imaging signal from the CCD at that moment is transferred to and stored in a memory device 1308. Further, the digital still camera 1300 is provided with video signal output terminals 1312 and an input/output terminal 1314 for data communication disposed on a side surface of the case 1302. Further, as shown in the drawing, a television monitor 1430 and a personal computer 1440 are respectively connected to the video signal output terminals 1312 and the input/output terminal 1314 for data communication according to needs. Further, there is adopted the configuration in which the imaging signal stored in the memory device 1308 is output to the television monitor 1430 and the personal computer 1440 in accordance with a predetermined operation. Such a digital still camera 1300 incorporates the oscillator 50 provided with a function as a timing source for signal processing.

It should be noted that, the oscillator 50 as the electronic component according to an embodiment of the invention can also be applied to an electronic apparatus such as an inkjet ejection device (e.g., an inkjet printer), a laptop personal computer, a television set, a video camera, a video tape recorder, a car navigation system, a pager, a personal digital assistance (including one with a communication function), an electronic dictionary, an electric calculator, a computerized game machine, a word processor, a workstation, a video phone, a security video monitor, a pair of electronic binoculars, a POS terminal, a medical device (e.g., an electronic thermometer, an electronic manometer, an electronic blood sugar meter, an electrocardiogram measurement instrument, an ultrasonograph, and an electronic endoscope), a fish detector, various types of measurement instruments, various types of gauges (e.g., gauges for a vehicle, an aircraft, or a ship), and a flight simulator besides the personal computer (the mobile personal computer) shown in FIG. 5, the cellular phone shown in FIG. 6, and the digital still camera shown in FIG. 7.

### Moving Object

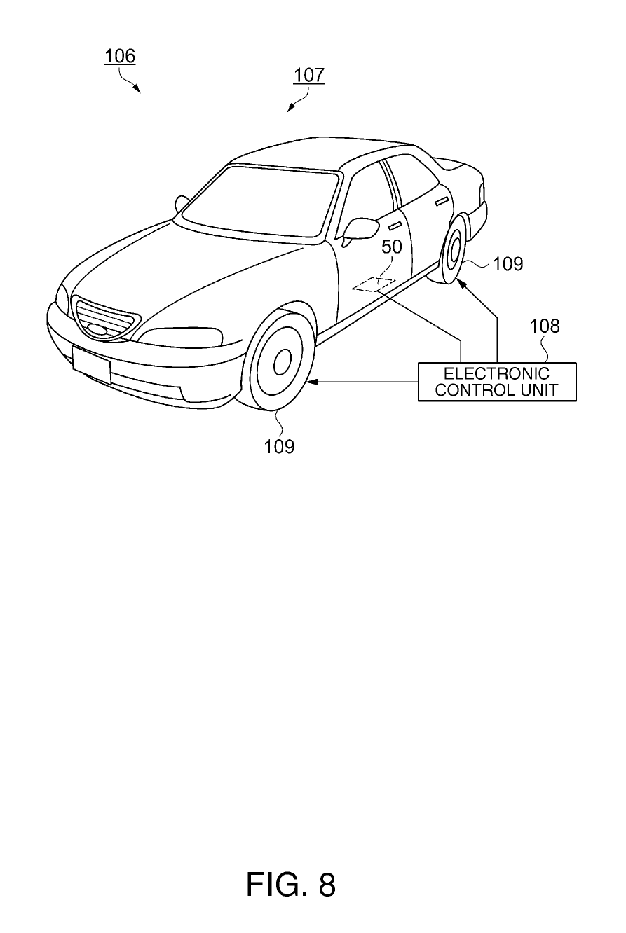

FIG. 8 is a perspective view schematically showing a vehicle as an example of the moving object. The vehicle 106 is equipped with the oscillator 50 as the electronic component according to the invention. For example, as shown in the drawing, in the vehicle 106 as the moving object, an electronic control unit 108 incorporating the oscillator 50 and for controlling tires 109 and so on is installed in a vehicle body 107. Further, besides the above, the oscillator 50 can widely be applied to an electronic control unit (ECU) such as a keyless entry system, an immobilizer, a car navigation system, a car air-conditioner, an anti-lock braking system (ABS), an air-bag system, a tire pressure monitoring system (TPMS), an engine controller, a battery monitor for a hybrid car or an electric car, or a vehicle posture control system.

The entire disclosure of Japanese Patent Application No. 2013-083821, filed Apr. 12, 2013 is expressly incorporated by reference herein.

What is claimed is:

1. An electronic component comprising:
a substrate;
a second connection electrode provided with a second hole extending from one surface of the substrate toward another surface, which is a reverse side with respect to the one surface, and a conductor disposed inside the second hole;
a first connection electrode adjacent to the second connection electrode, and provided with a first hole extending from the one surface toward the another surface, and a conductor disposed inside the first hole; and
a third connection electrode adjacent to the second connection electrode, and provided with a third hole extending from the one surface toward the another surface, and a conductor disposed inside the third hole,
wherein in a plan view of the one surface, a center of the second connection electrode is disposed at a position out of an imaginary line passing through a center of the first connection electrode and a center of the third connection electrode,
a second terminal electrically connected to the second connection electrode, a first terminal electrically connected to the first connection electrode, and a third terminal electrically connected to the third connection electrode are disposed on the one surface, and
the second terminal is disposed between the first terminal and the third terminal.

2. The electronic component according to claim 1, wherein
the substrate has a rectangular shape in the plan view of the one surface, and
a lateral electrode is disposed on a side surface connecting the one surface and the another surface to each other in a corner portion of the substrate.

3. The electronic component according to claim 1, wherein
the first terminal, the second terminal, and the third terminal have internal contact with an outer peripheral side of the substrate.

4. The electronic component according to claim 1, wherein
the first connection electrode is disposed inside the first terminal, the second connection electrode is disposed inside the second terminal, and the third connection electrode is disposed inside the third terminal in the plan view of the one surface.

5. The electronic component according to claim 1, further comprising:
a circuit element.

6. An electronic apparatus comprising:
the electronic component according to claim 1.

7. A moving object comprising:
the electronic component according to claim 1.
